(19) United States
(12) Patent Application Publication
(10) Pub. No.: US 2017/0250649 A1
(43) Pub. Date: Aug. 31, 2017

(54) IN-PLANE ROTATION SUN-TRACKING FOR CONCENTRATED PHOTOVOLTAIC PANEL

(71) Applicant: Panasonic Boston Laboratory, Newton, MA (US)

(72) Inventor: Xinbing Liu, Acton, MA (US)

(21) Appl. No.: 15/440,070

(22) Filed: Feb. 23, 2017

Related U.S. Application Data
(60) Provisional application No. 62/300,453, filed on Feb. 26, 2016.

(51) Int. Cl. H02S 20/32; H01L 31/05; H01L 31/054

(52) U.S. Cl. CPC H02S 20/32; H01L 31/0543; H01L 31/0508

(57) ABSTRACT

A photovoltaic array includes a two-dimensional array of photovoltaic cells having a plurality of rows, each row having a pivot axis parallel to the row. Each cell has a lens which has a front surface configured to concentrate light normal to the front surface onto the photovoltaic element. The photovoltaic array further includes a rotational actuator, coupled to the array of photovoltaic cells configured to rotate the array of photovoltaic cells about an axis perpendicular to a plane defined by the array of photovoltaic elements and a tilt actuator, coupled to each of the rows of photovoltaic elements configured to pivot the rows of photovoltaic elements about their pivot axes.

### CROSS REFERENCE TO RELATED APPLICATIONS

This application claims priority to U.S. Provisional Patent Application No. 62/300,453, filed Feb. 26, 2016, the contents of such application being incorporated by reference herein.

### STATEMENT REGARDING FEDERALLY SPONSORED RESEARCH

This invention was developed under Contract DE-AR0000629 between Panasonic North America and the U.S. Department of Energy. The U.S. Government has certain rights in this invention.

### BACKGROUND OF THE INVENTION

There are two categories of solar photovoltaic (PV) panels: regular PV panel and concentrated photovoltaic (CPV) panel. While the regular solar panel covers the entire panel with photovoltaic cells for electricity generation, the CPV panel uses optical components (e.g., lenses) to focus the sunlight to a small spot where a small PV cell is placed to receive the concentrated sunlight to generate electricity. CPV is typically used with high-efficiency but more expensive PV cells, such as multi-junction solar cells based on GaAs substrate, so a smaller number of the expensive PV cells may be used for the panel to save cost. CPV has the advantage of higher solar energy conversion efficiency than the typical crystalline silicon PV because it can use smaller multi-junction cells having much higher efficiency (˜40% vs. ˜20%).

Conventional CPV installations include CPV panels that are mounted on expensive precision dual-axis mechanical tracking systems. These dual-axis mechanical tracking systems are required in order for the CPV panel to properly track the sun. These systems, however, are bulky, expensive, and require the entire CPV panel to tilt in two axis. Due to this limitation, conventional CPV systems are typically mounted on the ground (not on rooftops).

### SUMMARY OF THE INVENTION

A photovoltaic array includes a two-dimensional array of photovoltaic cells having a plurality of rows, each row having a pivot axis parallel to the row. Each cell has a lens which has a front surface configured to concentrate light normal to the front surface onto the photovoltaic element. The photovoltaic array further includes a rotational actuator, coupled to the array of photovoltaic cells configured to rotate the array of photovoltaic cells about an axis perpendicular to a plane defined by the array of photovoltaic elements and a tilt actuator, coupled to each of the rows of photovoltaic elements configured to pivot the rows of photovoltaic elements about their pivot axes.

### BRIEF DESCRIPTION OF THE DRAWINGS

The invention may be understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1A is a perspective view of a lenslet row of the concentration optics;

FIG. 1B is a side-plan view of a portion of a CPV array showing multiple lenslet rows of the concentration optics;

FIG. 1C is a top-plan view of the CPV array including example concentration optics.

FIG. 2 is a perspective drawing of the example CPV array which is useful for describing the operation of an example drive system.

FIGS. 3A, 3B and 3C are top-plan views of the CPV array in different orientations that is useful for describing daily sun tracking by the CPV array.

FIG. 4A is a perspective view of the CPV array that is useful for describing seasonal sun tracking by the CPV array.

FIG. 4B is a side-plan view of a portion of the CPV array that is useful for describing seasonal sun tracking by the CPV array.

FIG. 5 is a block diagram of an example system including the photovoltaic array, drive system and controller.

FIGS. 6, 7 and 8 are block diagrams of example controllers suitable for use in the system shown in FIG. 5.

### DETAILED DESCRIPTION OF THE INVENTION

It is desirable for CPV panels to always directly face the sun for the concentrating optics to function properly, and therefore today the panels must be mounted on expensive precision tracking systems. This means that CPV systems occupy a lot of land and the panels cannot be mounted on a rooftop.

The system disclosed herein provides a micro-CPV panel with integrated tracking mechanism that does not need the whole panel to tilt to follow the sun. A micro-CPV panel uses thousands of small lenses and PV cells in a low-profile panel rather than a few large ones. This enables the panel to be mounted at a fixed tilt orientation without the cumbersome and expensive full two-axis tracking. This will greatly expand the CPV technology and market to places heretofore unavailable to CPV, such as in urban areas with many rooftops that are unsuitable for conventional CPV panels.

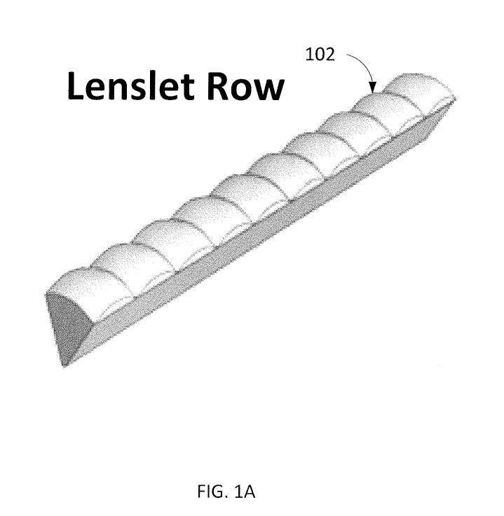

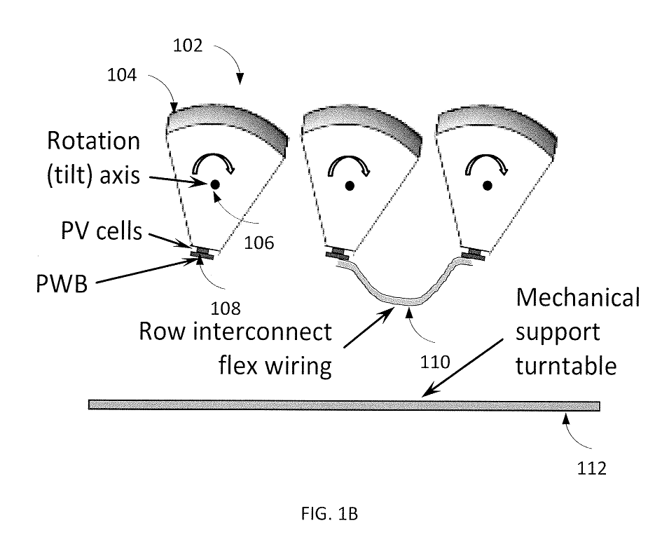

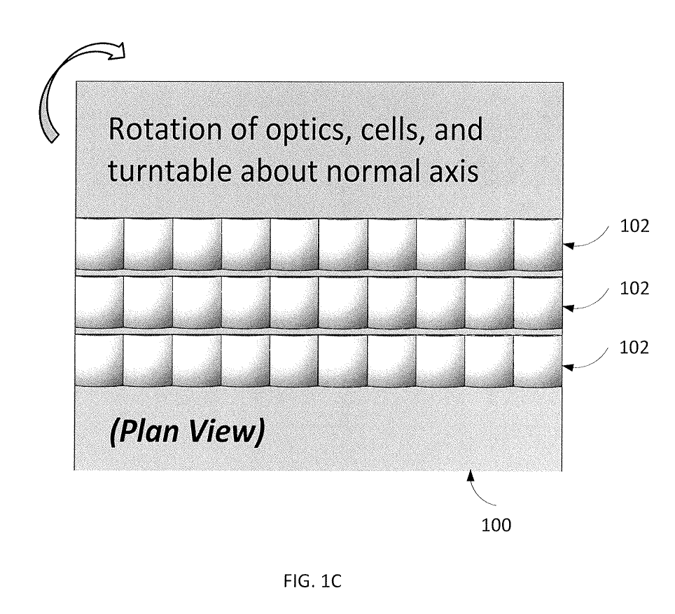

The integrated tracking mechanism disclosed herein is shown in FIGS. 1A, 1B and 1C is called in-plane rotation (IPR). The concentration optics are rows of lenslets 102. Each lenslet has one front power surface 104 that focuses the sunlight towards the back surface 108 of the lenslet, which is flat and where the solar cell (photovoltaic) element is attached, as shown in FIGS. 1A and 1B. Each row 102 tilts as a rigid body about its long axis 106. A second rotational axis is required to track the sun. This axis is normal to the CPV panel, so that the entire CPV panel rotates about this axis, and is illustrated in FIG. 1C. As shown in FIG. 1B, the rows of CPV cells may be interconnected via flexible wiring 110.

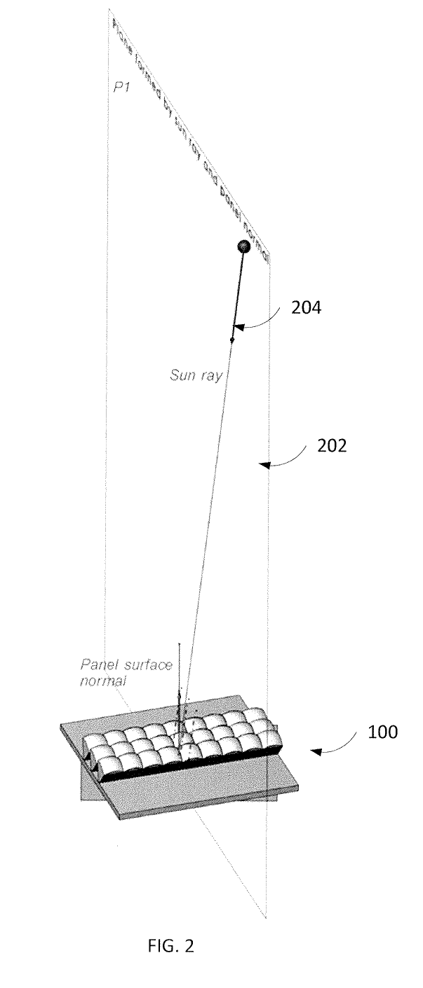

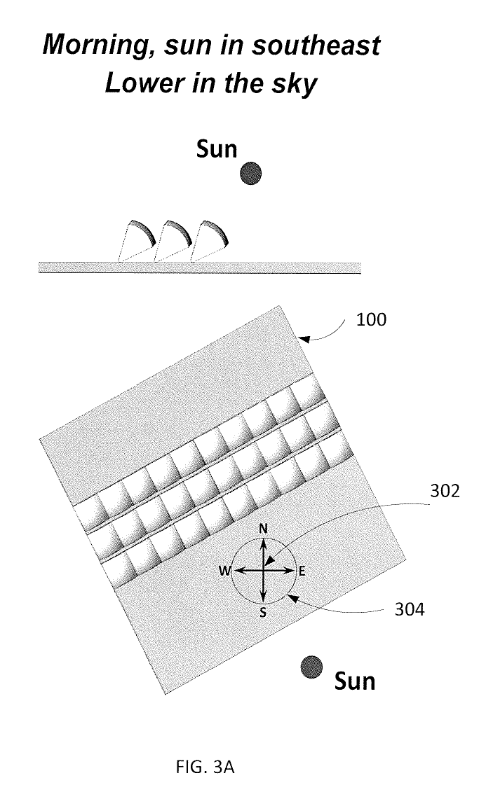

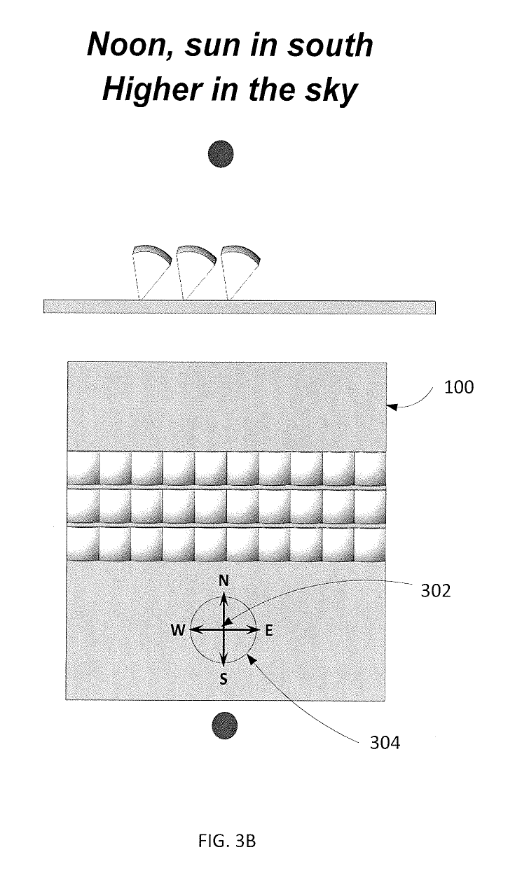

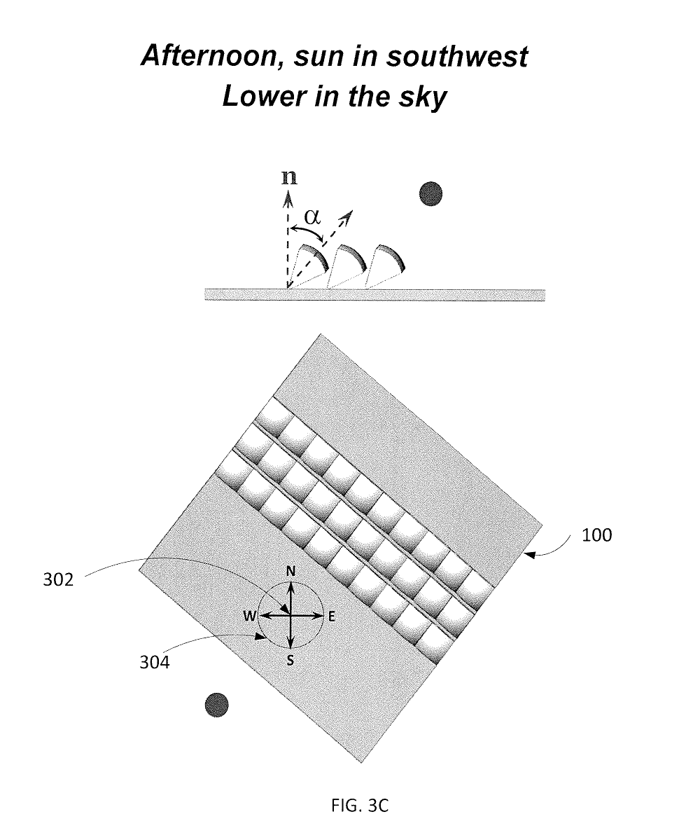

To track the sun, the rows of lenslets are made always to face the sun at normal incident angle. Referring to FIG. 2, the CPV panel 100 rotates in-plane so the lens array rows are perpendicular to the plane 202 formed by the sun ray and the surface normal of the panel. Then the lens array rows 102 pivot about their axes 106 to face the sun at normal incidence. The surface normal of the CPV panel 100 and the sun's rays form a plane, 202, as shown in FIGS. 2 and 3A-3C. The panel is rotated in-plane around the panel normal 302 so the axis of each lens row is maintained perpendicular to the plane P1. The lens rows are then tilted so that the lens optical axis is parallel to the sun's rays. FIGS. 3A-3C show how the CPV panel 100 tracks the sun across the sky. The rotation of the CPV 100 may be achieved using a pancake stepper motor 304 (shown in phantom) mounted below the CPV panel 100. Alternatively, the rotational motor 304 may be a stepper motor (not shown) having a helical lead screw (not shown) that engages a radial gear (not shown) mounted on the bottom of the CPV panel 100.

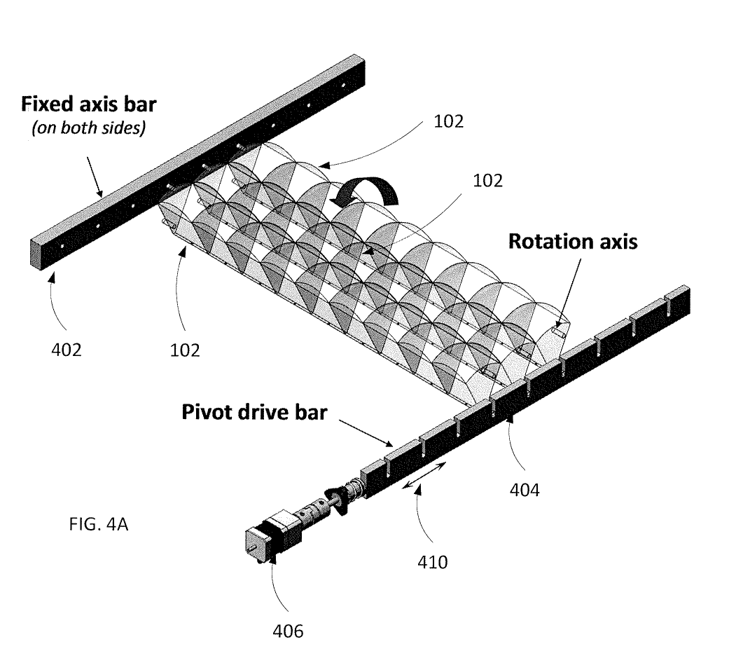

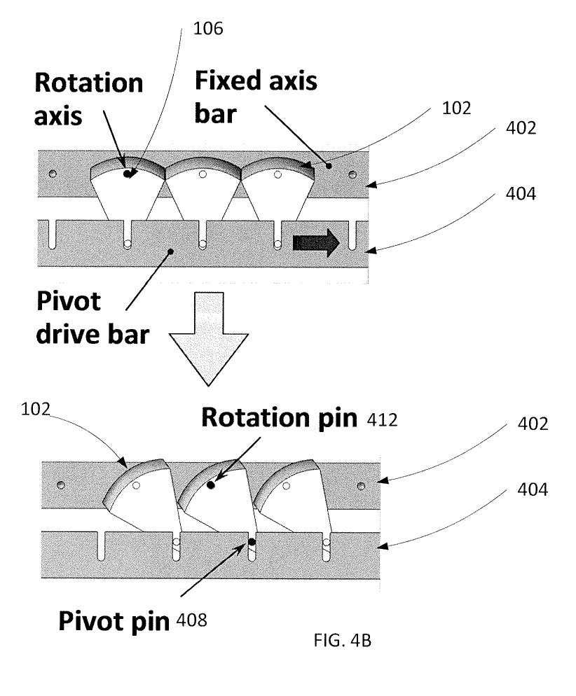

FIG. 4A shows a schematic of how the rows of lenslets can be pivoted together in the CPV panel plane. The in-plane rotation of the CPV panel is driven by the rotation motor 304. As shown in FIG. 4A, tilt motor 406 includes a helical lead screw that engages with gear teeth on the pivot bar 404. The pivot bar 404 is coupled to a rotation pin 412 at one end of each of the lenslet arrays 102. The other end of the lenslet array includes a pivot pin 408 that is coupled to a pivot bar as shown in FIG. 4B. Linear motion in the direction shown by the arrow 410 in FIG. 4A causes all of the lenslet arrays to pivot about the axis 106 and, by doing so, to tilt to the same angular direction a relative to a vector normal to the CPV panel 100, as shown in FIG. 3C.

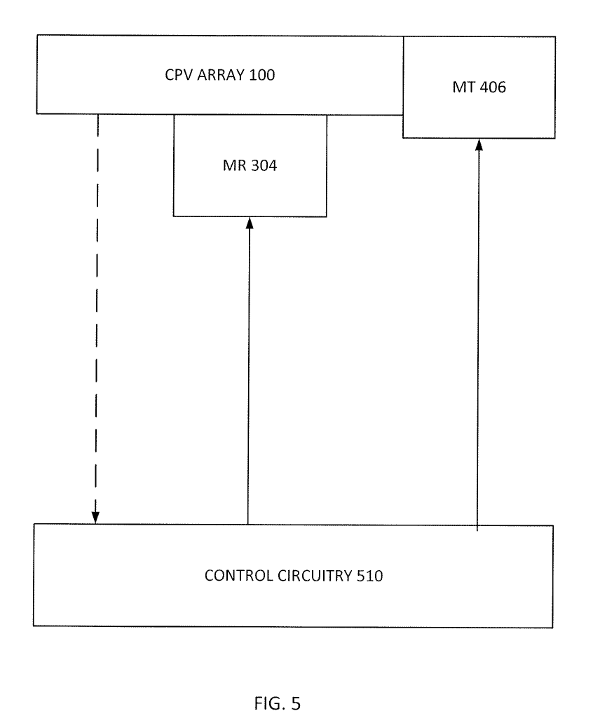

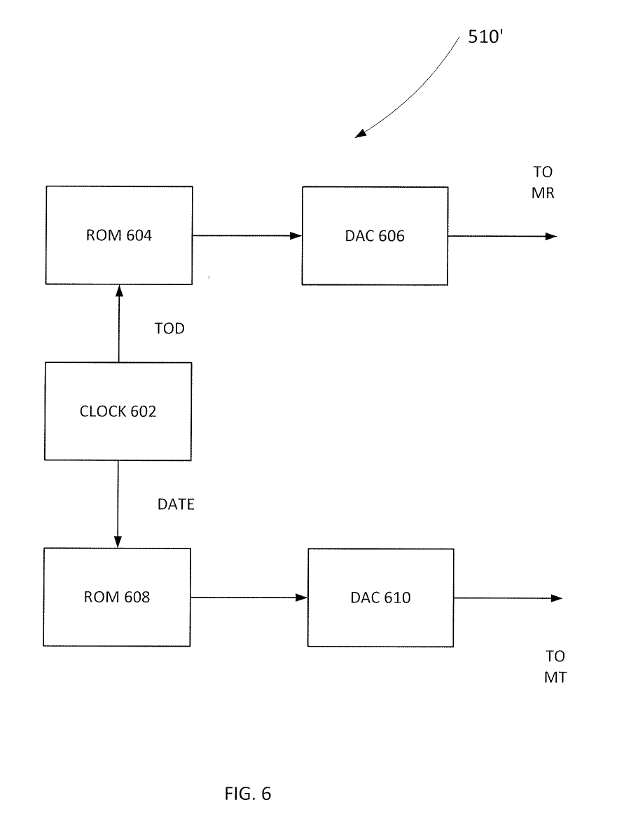

FIG. 5 is a block diagram of an example CPV system including the CPV panel 100, drive motors 304 and 406 and control circuitry 510. As shown in FIG. 5, the control circuitry controls the rotational motor 304 and the tilt motor 406 to orient the rows of CPV cells toward the sun. As described below with reference to FIGS. 6, 7 and 8, the controller may be an open loop system or a closed loop system. If it is a closed loop system, the control circuitry 510 may receive a feedback signal from the CPV array 100.

FIG. 6 is a block diagram of an example open loop system 510′. This system is driven by a clock circuit 602 that provides time of day (TOD) values and date of year (DATE) values. In this example, the clock circuit 602 may be a free-running clock that is manually set on installation and has an interface so that it may be manually recalibrated. Alternatively, it may be automatically calibrated. The clock may be automatically calibrated using the NIST time signals broadcast by the WWV radio station. Alternatively, it may be automatically calibrated using a GPS time signal. In another alternative, it may be automatically calibrated based on the output signal of the CPV array 100. This type of calibration may align an increase in light output from the array with sunrise, a decrease in light output with sunset, or a median between the increase and decrease with noon.

In the example shown in FIG. 6, the TOD value is applied to a read-only memory (ROM) 604 that contains data values corresponding to motor drive signals that cause the rotational motor 304 to rotate the CPV array 100 such that sunlight received by each lens element of the upper concentration element 102 is directed at a horizontal angle normal to the CPV cells of the CPV array 100. The ROM 604 is programmed to provide values appropriate for the daily change in the angle of the sun. The data values provided by the ROM 604 are converted to analog signals by a digital-to-analog converter (DAC) 606 and are applied to the rotational motor 304 to rotate the CPV array in the horizontal plane so that the CPV cells face the sun.

Similarly, the DATE value is applied to a ROM 608 that produces data values that, when converted to analog values by the DAC 610, cause the tilt motor to tilt the rows of CPV cells about their rotation axes 106 to an angle appropriate for the day of the year such that the optical axis of each of the CPV cells is parallel to the rays from the sun.

While the ROMs 604 and 608 are shown as being separate, it is contemplated that they may be combined into a single ROM which produces values to control both the rotational and tilt motors. This may be advantageous to control the rotational and tilt angles as a function of both the TOD and Date values.

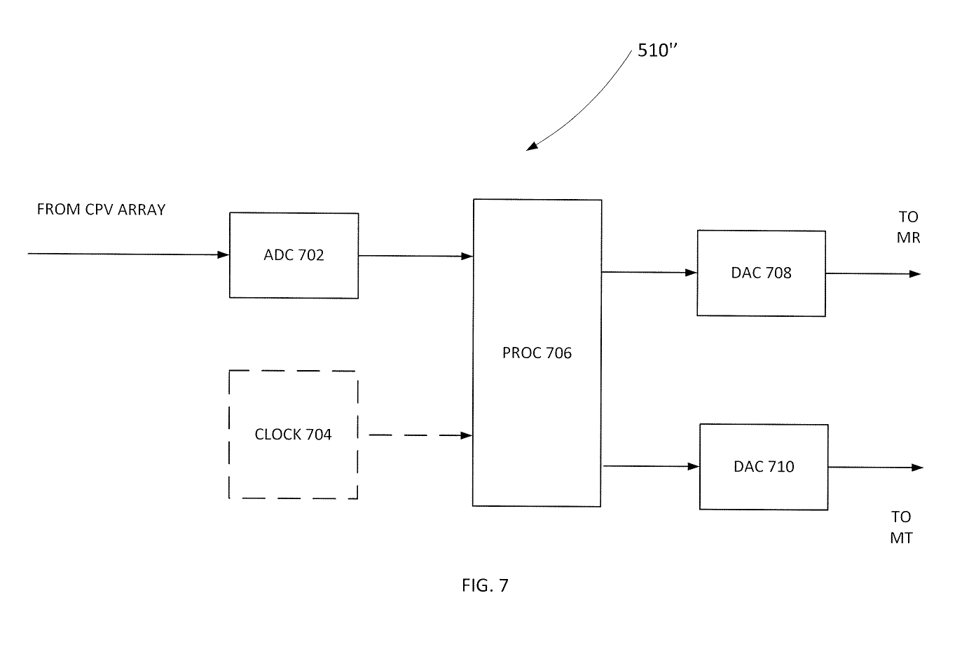

FIG. 7 is a block diagram of an example digital closed-loop control system 510″. This system receives an output signal from the CPV array 100. The output signal may be a signal that is proportional to the electrical output of the CPV array or it may be a dedicated signal that indicates the angle of sunlight impinging on the CPV array. The dedicated signal may be generated, for example, using a dedicated element including a lens (not shown) positioned above a two-dimensional array of PV elements (not shown). These PV elements may be positioned separately from but parallel to the CPV array. The direction of the sunlight impinging on the CPV array may be determined by interpolation of the relative output signals of the PV elements in the two-dimensional array.

The output signal from the CPV array 100 is digitized by an analog-to-digital converter (ADC) 702 and applied to a processor 706. The processor 706 may be, for example, a microcontroller, microprocessor or digital signal processor (DSP) including one or more central processing units (CPUs) and memory (not separately shown) configured to hold program instructions and data. It is contemplated that this memory may include both random access memory (RAM) and ROM. The processor 706 provides output data values to DACs 708 and 710 which are configured to drive the rotational motor 304 and tilt motor 406, respectively.

Optionally, the processor may also receive TOD and/or DATE signals from a clock circuit 704. This clock circuit may be similar to the clock circuit 602 described above with reference to FIG. 6. This clock signal may be used to place the processor 706 in a standby mode during the night hours.

When the signal from the PV array is proportional to the output signal of the CPV array, the processor may periodically adjust digital control values applied to the DAC 708 to incrementally rotate the CPV array. After an incremental rotation, the processor 706 measures any change in the output signal of the CPV array. If the processor 706 measures an increased output signal, it may continue to rotate the CPV array 100 until it detects a decreased output signal. It then may change the data value applied to the DAC 708 to be the value corresponding to the highest output signal. To compensate for variations in output caused, for example, by transitory shadows on the CPV panel 100, the processor may repeat the measurement one or more times and average the results. Alternatively, or in addition, it may measure output signals one or more times over a wider rotational range and fit the values to a curve. The digital value applied to the DAC 708 may then be set to correspond to the peak of the curve.

The signals applied to the DAC 710 and, thus, to the tilt motor 406, may be determined similarly but with a longer delay between updates. The signal applied to the tilt motor may be determined for example, on a daily or weekly basis or more frequently depending on a seasonal shift indicated by the clock 704. For example, tilt adjustments may occur more frequently at dates near the equinoxes than at dates near the solstices.

When the signal from the PV array 100 is provided by the dedicated two-dimensional array of PV cells, the processor 706 may determine the angle of incident sunlight from the output voltages of the cells in the dedicated array and adjust the signals applied to the DACs 708 and 710 to a rotation and tilt that matches this angle.

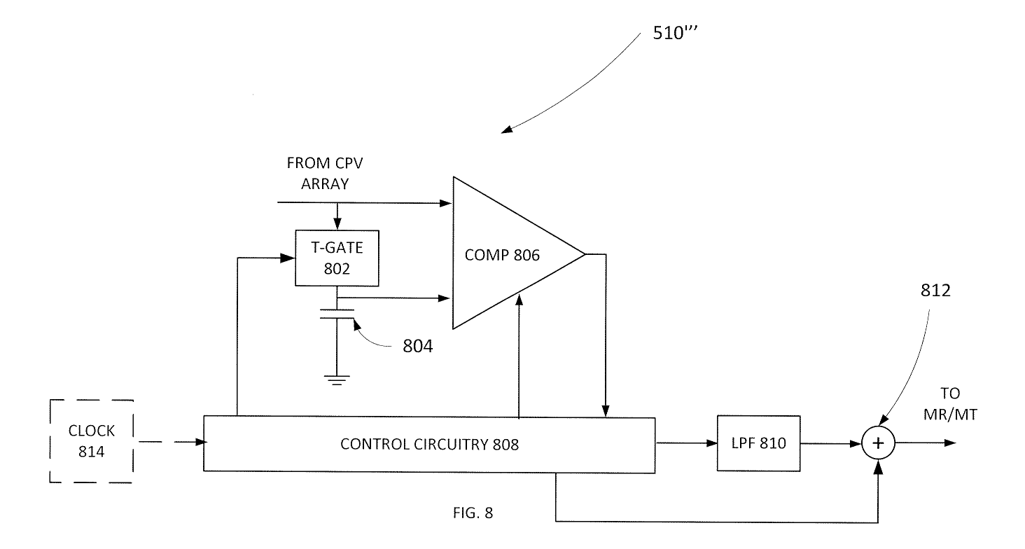

FIG. 8 is a block diagram of an example analog or partially analog controller 510″. In this implementation, control circuitry 808 controls a transmission gate 802 to store a current output value of the CPV array 100 on a capacitor 804. The control circuitry then adjusts an analog signal applied to the rotational motor 304 (or tilt motor 406), via an analog adder 812 to rotate the CPV array (or to tilt the rows 102 of CPV elements). After moving the rows of elements, the control circuitry causes the comparator 806 to compare the output signal from the CPV array 100 to the value stored on the capacitor 804. If this comparison indicates an increase in the output of the array 100, the control circuitry increases a base signal applied to a low-pass filter (LPF) 810, the output signal of which is applied to another input terminal of the analog adder 812. The low-pass filter 810 smoothes the signal applied to the respective motor 304 or 406 to compensate for transient shadows on the CPV array 100. The control circuitry 808 may also receive a control signal from clock circuitry 814 which operates similarly to the circuitry 704, described above with reference to FIG. 7.

While the examples described above show stepper motors driving the upper and lower concentration elements, it is contemplated that other technologies, such as linear motors or hydraulic actuators may be used.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A photovoltaic array comprising:
a two-dimensional array of photovoltaic cells having a plurality of rows, each row of photovoltaic cells having a pivot axis parallel to the row, each cell having a lens having a front surface configured to concentrate light normal to the front surface onto the photovoltaic element;
a rotational actuator, coupled to the array of photovoltaic cells configured to rotate the array of photovoltaic cells about an axis perpendicular to a plane defined by the array of photovoltaic elements; and
a tilt actuator, coupled to each of the rows of photovoltaic elements to pivot the rows of photovoltaic elements about their pivot axes.

2. The photovoltaic array of claim 1, further comprising:
a stepper motor as the rotational actuator for rotating the array of photovoltaic elements; and
a motor with a helical lead screw as the tilt actuator for pivoting the rows of photovoltaic elements.

3. The photovoltaic array of claim 1, further comprising:
flexible wiring electrically connecting the photovoltaic cells to each other.

4. The photovoltaic array of claim 1, further comprising:
a fixed axis bar connected to of each of the rows by a first pin; and
a pivot driver bar connected to each of the rows by a second pin,
wherein the tilt actuator pivots the rows by moving the pivot driver bar relative to the fixed axis bar.

5. The photovoltaic array of claim 1, further comprising:
an open loop controller for controlling the rotational actuator and the tilt actuator to track sunlight based on time of day values and date of year values provided by a clock circuit.

6. The photovoltaic array of claim 1, further comprising:
a closed loop controller for controlling the rotational actuator and the tilt actuator to track sunlight based on time of day values and date of year values provided by a clock circuit, and based on a signal output by the array.

7. The photovoltaic array of claim 1, further comprising:
a partially analog controller for controlling the rotational actuator and tilt actuator to track sunlight based on time of day values and date of year values provided by a clock circuit, and based on an analog comparison between a present signal output by the array and a previous signal output by the array stored in a capacitor.

8. A method for controlling a photovoltaic array including a two-dimensional array of photovoltaic cells having a plurality of rows, each row of photovoltaic cells having a pivot axis parallel to the row, each cell having a lens having a front surface configured to concentrate light normal to the front surface onto the photovoltaic element, the method comprising:
rotating, by a rotational actuator coupled to the array of photovoltaic cells, the array of photovoltaic cells about an axis perpendicular to a plane defined by the array of photovoltaic elements; and
tilting, by a tilt actuator coupled to each of the rows of photovoltaic elements, the rows of photovoltaic elements to pivot about their pivot axes.

9. The method of claim 8, further comprising:
rotating, by a stepper motor as the rotational actuator, the array of photovoltaic elements; and
tilting, by a motor with a helical lead screw as the tilt actuator, the rows of photovoltaic elements.

10. The method of claim 8, further comprising:
conducting, by flexible wiring electrically connecting the photovoltaic cells, electrical current between the cells.

11. The method of claim 8, further comprising:
pivoting, by a tilt actuator, the rows of the array by moving a pivot driver bar connected to each of the rows by a second pin relative to a fixed axis bar connected to of each of the rows by a first pin.

12. The method of claim 8, further comprising:
controlling, by an open loop controller, the rotational actuator and tilt actuator to track sunlight based on time of day values and date of year values provided by a clock circuit.

13. The method of claim 8, further comprising:
controlling, by a closed loop controller, the rotational actuator and the tilt actuator to track sunlight based on time of day values and date of year values provided by a clock circuit, and based on a signal output by the array.

14. The method of claim 8, further comprising:
controlling, by a partially analog controller, the rotational actuator and the tilt actuator to track sunlight based on time of day values and date of year values provided by a clock circuit, and based on an analog comparison between a present signal output by the array and a previous signal output by the array stored in a capacitor.
